(19) United States
(12) Patent Application Publication
(10) Pub. No.: US 2015/0126681 A1
(43) Pub. Date: May 7, 2015

(54) ORGANIC-INORGANIC COMPOSITE FILM AND METHOD FOR MANUFACTURING THE SAME

(71) Applicant: INDUSTRIAL TECHNOLOGY RESEARCH INSTITUTE, Hsinchu (TW)

(72) Inventors: Lik-Hang CHAU, Tainan City (TW); Chih-Hao LIANG, Changhua County (TW); Hsi-Hsin SHIH, Taichung City (TW); Chih-Chao YANG, Tainan City (TW); Yi-Tsung PAN, Tainan City (TW)

(21) Appl. No.: 14/590,633

(22) Filed: Jan. 6, 2015

Related U.S. Application Data
(63) Continuation-in-part of application No. 14/070,777, filed on Nov. 4, 2013.

(30) Foreign Application Priority Data
Aug. 27, 2013 (TW) 102130532

(51) Int. Cl. C09D 127/16; C23C 14/34; C09D 127/18

(52) U.S. Cl. CPC C09D 127/16; C09D 127/18; C23C 14/34
USPC 525/326.2; 204/192.1

(57) ABSTRACT

A method of manufacturing an organic-inorganic composite film is provided. The method includes co-sputtering an inorganic target and a fluorine-containing organic polymer target, thereby simultaneously depositing atoms from the inorganic target and atoms from the fluorine-containing organic polymer target on a substrate. As such, an organic-inorganic composite film is obtained. The organic-inorganic composite film includes a homogeneous, amorphous, and nonporous material composed of carbon, fluorine and/or chlorine, oxygen and/or nitrogen, and inorganic element M. The inorganic element M forms chemical bondings with carbon, fluorine, chlorine, oxygen and/or nitrogen, and wherein the bond length forms therefore is less than 2.78 Å.

### CROSS REFERENCE TO RELATED APPLICATIONS

This application is a Continuation-In-Part of pending U.S. patent application Ser. No. 14/070,777, filed on Nov. 4, 2013 and entitled “Organic-inorganic composite film and method for manufacturing the same”, which claims priority from, Taiwan Application Serial Number 102130532, filed on Aug. 27, 2013, the disclosure of which is hereby incorporated by reference herein in its entirety

### TECHNICAL FIELD

The technical field relates to an organic-inorganic composite film, and in particular relates to a method for manufacturing the same.

### BACKGROUND

In a flexible electronic substrate, a soft material with a support function may serve as a circuit substrate to be continuously curved several times. The flexible electronic substrate is different from conventional electronic elements in that it can be widely applied in many fields, such as flexible displays, organic light-emitting diodes, radio-frequency identification systems, and the likes. The optical plastic material with transparency and processability can be widely applied in displays and flexible light-emitting devices. Because thin-film substrates composed of the plastic material are highly flexible, arbitrarily deformable, and light-weight, they can be applied in many products.

With each generation, device size shrinks, and the number of multi-layered layout and logic interconnect layers increases. As such, the capacitance between the conductive lines, the capacitance between the layers, and the resistance of the conductive lines increase correspondingly. Therefore, the RC time delay not only limits the operational speed of the device, but also consumes the device's energy. For reducing RC time delay and power loss, a metal of low resistivity (e.g. copper) can be used to replace aluminum. In addition, the parasitic capacitance (C) of the dielectric layer should be further reduced. Because the parasitic capacitance is positively related to the dielectric constant (k) of the dielectric layer, a novel low-k material for the dielectric layer is called for.

Currently developed insulator dielectric material SiO₂ (k=3.9 to 4.2) cannot satisfy the requirements of ULSI. Dielectric materials that serve as an inter-metal dielectric layer should meet the requirements of high reliability, low stress, easy processing, low water absorption, and easy integration with metal lines. Conventional dielectric materials, e.g. silicon oxide formed by plasma-enhanced chemical vapor deposition (PECVD), have a dielectric constant of 3.9 to 4.2. Other common dielectric materials, e.g. SiO₂-based material or siloxane-based material, often have a dielectric constant greater than 3.0. As semiconductor technology develops, it demands a dielectric material with a lower dielectric constant to match the device miniaturization for reducing time delay (of signal transmission), power loss, and crosstalk.

In addition, the organic material has a low water-blocking and oxygen-blocking ability, thereby reducing the reliability and lifetime of an organic device sensitive to water or oxygen. For reinforcing the water/oxygen-blocking ability of the plastic substrate, a material is usually densely coated thereon to prevent water/oxygen permeation and diffusion. The material, such as aluminum oxide (Al₂O₃) or silicon oxide (SiO₂), forms what is called a barrier layer. The silicon oxide has a light transmittance (>85%) satisfying the light transmittance requirement of organic light-emitting diodes (OLED). However, silicon oxide cannot be applied to OLED due to non-flexibility and poor water-blocking ability. The major water/oxygen barrier layers are usually multi-layered structures formed by sputtering or PECVD. However, the multi-layered structures exhibit problems such as complex processing, high cost, and the likes.

Accordingly, a novel method for manufacturing a film with a low dielectric constant, a high flexibility, and a low water vapor/oxygen transmittance is called-for.

### SUMMARY

One embodiment of the disclosure provides an organic-inorganic composite film, comprising: homogeneous, amorphous, and nonporous material composed of carbon, fluorine, chlorine, oxygen and/or nitrogen, and inorganic element M, wherein the inorganic element M forms chemical bondings with carbon, fluorine, chlorine, oxygen and/or nitrogen, and wherein the chemical bondings have a bond length less than 2.78 Å.

One embodiment of the disclosure provides a method of manufacturing an organic-inorganic composite film, comprising: co-sputtering an inorganic target and a fluorine-containing organic polymer target, thereby simultaneously depositing atoms from the inorganic target and atoms from the fluorine-containing organic polymer target on a substrate to form an organic-inorganic composite film.

One embodiment of the disclosure provides a method of manufacturing an organic-inorganic composite film, comprising: co-sputtering a titanium oxide (TiO2) target and a polytetrafluoroethylene (PTFE) target, thereby simultaneously depositing atoms from the titanium oxide target and atoms from the polytetrafluoroethylene target on a substrate to form an organic-inorganic composite film.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows an XRD spectrum of an organic-inorganic composite film in one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

One embodiment of the disclosure provides a method for manufacturing an organic-inorganic composite film. An inorganic target and a fluorine-containing organic polymer target are co-sputtered, thereby simultaneously depositing atoms from the inorganic target and atoms from the fluorine-containing organic polymer target on a substrate. In one embodiment, the co-sputtering process can be performed by a commercially available sputter, such as a vacuum chamber sputter commercially available from Chinese United Semiconductor Equipment Manufacturing Inc. In one embodiment, the chamber pressure is 1×10⁻² torr to 1×10⁻³ torr, and the substrate temperature is 25° C. to 150° C. during the co-sputtering process. In the co-sputtering process, a gas mixture of an inert gas (e.g. argon) and a reaction gas (e.g. oxygen) is introduced into the chamber to control the chamber pressure. Sputtering power of 10 W to 500 W can be applied to the inorganic target and the fluorine-containing organic polymer target by a radio-frequency (Rf) power supply. In one embodiment of the disclosure, the sputtering power applied to the inorganic target is similar to the sputtering power applied to the fluorine-containing organic polymer target. Alternatively, the sputtering power applied to the inorganic target is different from the sputtering power applied to the fluorine-containing organic polymer target, and the difference depends on the requirements.

In one embodiment, the inorganic target can be silicon, silicon oxide, silicon nitride, silicon oxynitride, silicon carbide, titanium, titanium oxide, titanium fluoride, titanium nitride, titanium carbide, vanadium, vanadium oxide, vanadium nitride, vanadium carbide, aluminum, aluminum oxide, aluminum fluoride, aluminum nitride, chromium, chromium oxide, chromium nitride, chromium carbide, selenium, selenium oxide, selenium carbide, gallium, gallium oxide, gallium nitride, germanium, germanium oxide, germanium carbide, cobalt, cobalt oxide, iron, iron oxide, iron fluoride, iron carbide, palladium, palladium oxide, or combinations thereof. In one embodiment, the fluorine-containing organic polymer target can be polyvinylidene difluoride, (PVDF), polytetrafluoroethylene (PTFE), or combinations thereof. If the fluorine atomic ratio of the fluorine-containing organic polymer is higher, the fluorine atomic ratio of the organic-inorganic composite film will be higher, which further enhances the water/gas-blocking ability and reducing the dielectric constant of the organic-inorganic composite film. In one embodiment, the substrate can be a common substrate, such as polyethyleneterephthalate (PET) or polyethylene naphthalate (PEN). The organic-inorganic composite film obtained through the described processes is a homogeneous, amorphous, nonporous, and low-k material. The term “homogeneous” means that there is no interface between the organic material and the inorganic material. In other words, the inorganic material does not aggregate to form particles dispersed in the organic material. Analyzed by XRD, the organic-inorganic composite film is amorphous. In addition, the sputtering deposition may form a dense film without pores. In one embodiment, the organic-inorganic composite film includes 1 atomic % to 25 atomic % of carbon, 5 atomic % to 30 atomic % of fluorine, 30 atomic % to 65 atomic % of oxygen and/or nitrogen, and 10 atomic % to 50 atomic % of the inorganic element M (such as silicon, titanium, aluminum, chromium, selenium, gallium, germanium, nickel, cobalt, iron, or combinations thereof). For example, an organic-inorganic composite with a thickness of 10 nm to 10 μm has a dielectric constant of 2 to 2.5, a light transmittance of 90% to 95%, a radius of curvature of 2 mm to 5 mm. and a water vapor transmission rate of less than 15 mg/m²·day.

There are several criteria for achieving a water transport barrier thin film. First, the thin film does not have a grain boundary. Second, the chemical bonding length between the inorganic element M and carbon, fluorine, chlorine, oxygen and/or nitrogen is similar or shorter than the size of water molecule. Third, the cages formed by the amorphous network have extensive number of bonding connections. And lastly, at least some of the amorphous cages formed from these chemical bondings in the thin film are flexible.

If the thin film possesses a grain boundary, the width of the grain boundary is typically wider than water molecule. Water molecules can easily squeeze though grain boundaries. The transport of the water molecule is at best delayed, but not impeded. The amorphous thin film of the disclosure does not have grain boundaries.

Flexible bondings can be achieved by co-sputtering the inorganic target and the organic target. Inorganic element M can form chemical bondings with carbon, fluorine, chlorine, oxygen and/or nitrogen, and the bond length can be selected from the atomic radius of each constituent element. The bond length of the inorganic element M forms can be shorter than the water molecular (2.78 Å). For example, the inorganic element M can be silicon (1.11 Å), titanium (1.36 Å), aluminum (1.18 Å), chromium (1.27 Å), selenium (1.16 Å), gallium (1.26 Å), germanium (1.22 Å), nickel (1.21 Å), cobalt (1.26 Å), iron (1.25 Å), or combinations thereof.

The number of bonds that can be connected to any given M depends on the number of their valence electrons. For example, Selenium can connect up to six bonds (SeO₂, SeCl₄, Se₂Cl₂, SeF₄, SeF₆, Se₄N₄, Se₂C); Chromium can connect up to five bonds (CrO, CrO₂, CrO₃, CrO₅, Cr₂O₃, CrCl₂, CrCl₃, CrCl₄, CrF₂, CrN, Cr₃C₂, Cr₇C₃, Cr₂₃C₆); Titanium up to four bonds (TiO, TiO₂, Ti₂O₃, TiCl₂, TiCl₃, TiCl₄, TiF₄, TiN, TiC), Silicon up to four bonds (SiO₂, SiCl₄, SiF₄, Si₃N₄, SiC), Vanadium up to four bonds (VO, VO₂, V₂O₃, V₂O₅, VCl₂, VCl₃, VCl₄, VF₃, VN, VC), Germanium up to four bonds (GeO₂, GeCl₂, GeCl₄, GeF₄, Ge₃N₄, GeC), Palladium up to four bonds (PdO, PdCl₂, PdF₂, PdF₄, PdN₂, PdC); and Aluminum (Al₂O₃, AlCl₃, AlF₃, AlN, Al₄C₃), Gallium (Ga₂O₃, GaCl₃, GaF₃, GaN), Cobalt (CoO, Co₂O₃, Co₃O₄, CoCl₂, CoF₂, CoF₃, Co₂N, CoN, Co₂N₃, Co₂C), as well as Iron (FeO, Fe₂O₃, Fe₃O₄, FeCl₃, FeF₃, Fe₂N, Fe₄N, Fe₁₆N₂, Fe₃C) can connect up to three bonds.

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

The co-sputtering was performed by a vacuum chamber sputter system commercially available from Chinese United Semiconductor Equipment Manufacturing Inc.

The physical properties of the films were measured as below:

Chemical compositions of the films were analyzed by an X-ray energy dispersive spectrometer (5400, commercially available from JEOL).

Optical properties of the films were analyzed by a UV-VIS spectrometer (UV/Vis. Lambda 750, commercially available from PerkinElmer).

Dielectric constants of the films were analyzed by an impedance analyzer (Agilent 4284A, commercially available from Precision LCR Meter).

Water vapor transmission rates of the films were measured according to the standard of ASTM F1249.

Radius of curvature (Rc) of the films were measure according to the standard of ASTM D1593.

### Example 1

SiO₂ serving as an inorganic target was put into a chamber of the sputter system. PET with an area of 8 cm×8 cm serving as a substrate was put into the chamber. A gas mixture of an inert gas (argon with a purity of 4N, 20 sccm) and a reaction gas (oxygen with a purity of 4N, 10 sccm) was introduced into the chamber, and the chamber pressure was controlled to 5×10⁻³ Torr. Sputtering power of 200 W was applied to the SiO₂ inorganic target for 1 hour by a radio-frequency (RF) power supply, thereby forming a SiO₂ film with a thickness of 500 nm on the substrate. The inorganic film was brittle and without flexibility. The light transmittance, dielectric constant, and chemical compositions of the inorganic film are tabulated in Table 1.

### Example 2

SiO₂ serving as an inorganic target was put into a chamber of the sputter system. PVDF (purity greater than 99%, commercially available from Ultimate Materials Technology Company, Ltd.) with a volume of 0.5 cm×0.5 cm×0.5 cm serving as an organic polymer target was put into the chamber. PET with an area of 8 cm×8 cm serving as a substrate was put into the chamber. A gas mixture of an inert gas (argon with a purity of 4N, 20 sccm) and a reaction gas (oxygen with a purity of 4N, 10 sccm) was introduced into the chamber, and the chamber pressure was controlled to 5×10⁻³ Torr. Sputtering power of 200 W was simultaneously applied to the SiO₂ inorganic target and the PVDF organic polymer target for 1 hour by a radio-frequency (RF) power supply, thereby forming an organic-inorganic composite film with a thickness of 500 nm on the substrate. The organic-inorganic composite film had a radius of curvature of 2.5 mm. The light transmittance, dielectric constant, and chemical compositions of the organic-inorganic composite film are tabulated in Table 1.

### Example 3

Example 3 was similar to Example 2, and the difference of Example 3 was the volume of the PVDF organic polymer target was increased to 1.0 cm×0.5 cm×0.5 cm. The other processing factors of Example 3 were similar to those of Example 2 to obtain an organic-inorganic composite film with a thickness of 500 nm on the substrate. The organic-inorganic composite film had a radius of curvature of 2.5 mm. The light transmittance, dielectric constant, and chemical compositions of the organic-inorganic composite film are tabulated in Table 1.

### Example 4

Example 4 was similar to Example 2, and the difference of Example 4 was the volume of the PVDF organic polymer target was increased to 1.0 cm×1.0 cm×0.5 cm. The other processing factors of Example 4 were similar to those of Example 2 to obtain an organic-inorganic composite film with a thickness of 500 nm on the substrate. The organic-inorganic composite film had a radius of curvature of 2.5 mm. The light transmittance, dielectric constant, and chemical compositions of the organic-inorganic composite film are tabulated in Table 1.

### Example 5

Example 5 was similar to Example 2, and the difference of Example 5 was the volume of the PVDF organic polymer target was increased to 1.0 cm×1.2 cm×0.5 cm. The other processing factors of Example 5 were similar to those of Example 2 to obtain an organic-inorganic composite film with a thickness of 500 nm on the substrate. The organic-inorganic composite film had a radius of curvature of 2.5 mm. The light transmittance, dielectric constant, and chemical compositions of the organic-inorganic composite film are tabulated in Table 1.

### Example 6

SiO₂ serving as an inorganic target was put into a chamber of the sputter system. PTFE (purity greater than 99%, commercially available from Ultimate Materials Technology Company, Ltd.) with a volume of 0.5 cm×0.5 cm×0.5 cm serving as an organic polymer target was put into the chamber. PET with an area of 8 cm×8 cm serving as a substrate was put into the chamber. A gas mixture of an inert gas (argon with a purity of 4N, 20 sccm) and a reaction gas (oxygen with a purity of 4N, 10 sccm) was introduced into the chamber, and the chamber pressure was controlled to 5×10⁻³ Torr. Sputtering power of 200 W was simultaneously applied to the SiO₂ inorganic target and the PTFE organic polymer target for 1 hour by a radio-frequency (RF) power supply, thereby forming an organic-inorganic composite film with a thickness of 500 nm on the substrate. The organic-inorganic composite film had a radius of curvature of 2.5 mm. The light transmittance, dielectric constant, and chemical compositions of the organic-inorganic composite film are tabulated in Table 1.

### Example 7

Example 7 was similar to Example 6, and the difference of Example 7 was the volume of the PTFE organic polymer target was increased to 1.0 cm×0.5 cm×0.5 cm. The other processing factors of Example 7 were similar to those of Example 6 to obtain an organic-inorganic composite film with a thickness of 500 nm on the substrate. The organic-inorganic composite film had a radius of curvature of 2.5 mm. The light transmittance, dielectric constant, and chemical compositions of the organic-inorganic composite film are tabulated in Table 1.

### Example 8

Example 8 was similar to Example 6, and the difference of Example 8 was the volume of the PTFE organic polymer target was increased to 1.0 cm×1.0 cm×0.5 cm. The other processing factors of Example 8 were similar to those of Example 6 to obtain an organic-inorganic composite film with a thickness of 500 nm on the substrate. The organic-inorganic composite film had a radius of curvature of 2.5 mm. The light transmittance, dielectric constant, and chemical compositions of the organic-inorganic composite film are tabulated in Table 1.

### Example 9

Example 9 was similar to Example 6, and the difference of Example 9 was the volume of the PTFE organic polymer target was increased to 1.0 cm×1.2 cm×0.5 cm. The other processing factors of Example 9 were similar to those of Example 6 to obtain an organic-inorganic composite film with a thickness of 500 nm on the substrate. The organic-inorganic composite film had a radius of curvature of 2.5 mm. The light transmittance, dielectric constant, and chemical compositions of the organic-inorganic composite film are tabulated in Table 1.

TABLE 1

| | Light | | | | | |
|---|---|---|---|---|---|---|
| | transmittance | | Chemical compositions | | | |
| | (550 nm/400- | Dielectric | (atomic %) | | | |
| | 800 nm) | constant | C | O | F | Si |
| Example 1 | 92.5%/92.0% | 6.328 | 0 | 72.45 | 0 | 27.57 |
| Example 2 | 92.3%/91.9% | 5.427 | 1.66 | 71.31 | 0 | 27.03 |
| Example 3 | 91.8%/91.7% | 3.265 | 1.76 | 71.80 | 0.17 | 26.27 |
| Example 4 | 92.5%/92.0% | 2.938 | 1.21 | 71.08 | 1.48 | 26.22 |
| Example 5 | 90.8%/91.8% | 2.717 | 1.30 | 66.33 | 6.80 | 25.56 |
| Example 6 | 91.6%/91.1% | 2.033 | 2.08 | 62.69 | 4.74 | 30.49 |
| Example 7 | 91.8%/92.3% | 2.017 | 5.04 | 57.99 | 8.40 | 28.57 |
| Example 8 | 92.4%/92.1% | 2.095 | 3.39 | 57.45 | 10.11 | 29.05 |
| Example 9 | 92.2%/91.1% | 2.003 | 1.18 | 55.87 | 12.59 | 30.37 |

### Example 10

A commercially available PET film (Toyobo) was put at a temperature of 40° C. under a relative humidity of 60% for 60 hours, and then analyzed for its water vapor transmission rate (about 3000 mg/m²·day).

Si inorganic target with a diameter of 3 inches serving as an inorganic target was put into a chamber of the sputter. PTFE (purity greater than 99%, commercially available from Ultimate Materials Technology Company, Ltd.) with a diameter of 3 inches serving as an organic polymer target was put into the chamber. The PET film with an area of 8 cm×8 cm serving as a substrate was put into the chamber. A gas mixture of an inert gas (argon with a purity of 4N, 20 sccm) and a reaction gas (oxygen with a purity of 4N, 10 sccm) was introduced into the chamber, and the chamber pressure was controlled to 5×10⁻³ Torr. Sputtering power of 350 W was applied to the Si inorganic target, and sputtering power of 40 W was simultaneously applied to the PTFE organic polymer target for 3 hours by a radio-frequency (RF) power supply, thereby forming an organic-inorganic composite film with a thickness of 500 nm on the substrate. The organic-inorganic composite film had a radius of curvature of 2.5 mm. The organic-inorganic composite film was put at a temperature of 40° C. under a relative humidity of 60% for 60 hours, and then analyzed for its water vapor transmission rate (about 930 mg/m²·day).

### Example 11

TiO₂ inorganic target with a diameter of 3 inches serving as an inorganic target was put into a chamber of the sputter system. PTFE (purity greater than 99%, commercially available from Ultimate Materials Technology Company, Ltd.) with a diameter of 3 inches serving as an organic polymer target was put into the chamber. The PET film with an area of 8 cm×8 cm serving as a substrate was put into the chamber. A gas mixture of an inert gas (argon with a purity of 4N, 20 sccm) and a reaction gas (oxygen with a purity of 4N, 10 sccm) was introduced into the chamber, and the chamber pressure was controlled to 5×10⁻³ Torr. Sputtering power of 350 W was applied to the TiO₂ inorganic target, and sputtering power of 40 W was simultaneously applied to the PTFE organic polymer target for 3 hours by a radio-frequency (RF) power supply, thereby forming an organic-inorganic composite film with a thickness of 540 nm on the substrate. The organic-inorganic composite film had a radius of curvature of 2.5 mm. The organic-inorganic composite film was put at a temperature of 40° C. under a relative humidity of 60% for 70 hours, and then analyzed for its water vapor transmission rate (about 16 mg/m²·day).

### Example 12

A commercially available PEN film (Teijin) was put at a temperature of 40° C. under a relative humidity of 60% for 60 hours, and then analyzed for its water vapor transmission rate (about 1000 mg/m²·day).

Si inorganic target with a diameter of 3 inches serving as an inorganic target was put into a chamber of the sputter system. PTFE (purity greater than 99%, commercially available from Ultimate Materials Technology Company, Ltd.) with a diameter of 3 inches serving as an organic polymer target was put into the chamber. The PEN film with an area of 8 cm×8 cm serving as a substrate was put into the chamber. A gas mixture of an inert gas (argon with a purity of 4N, 20 sccm) and a reaction gas (oxygen with a purity of 4N, 10 sccm) was introduced into the chamber, and the chamber pressure was controlled to 5×10⁻³ Torr. Sputtering power of 350 W was applied to the Si inorganic target, and sputtering power of 40 W was simultaneously applied to the PTFE organic polymer target for 3 hours by a radio-frequency (RF) power supply, thereby forming an organic-inorganic composite film with a thickness of 600 nm on the substrate. The organic-inorganic composite film had a radius of curvature of 2.5 mm. The organic-inorganic composite film was put at a temperature of 40° C. under a relative humidity of 60% for 60 hours, and then analyzed for its water vapor transmission rate (about 114 mg/m²·day).

### Example 13

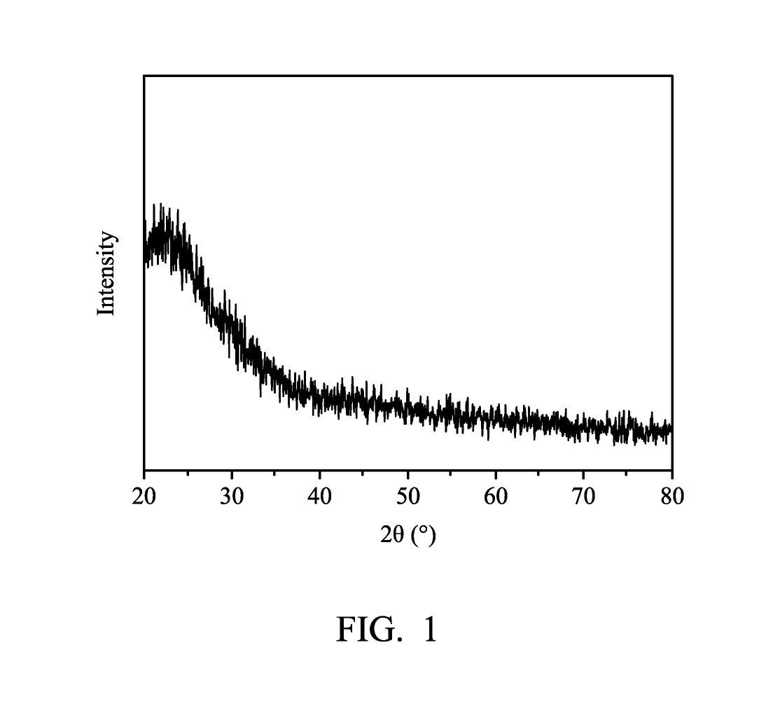

TiO₂ inorganic target with a diameter of 3 inches serving as an inorganic target was put into a chamber of the sputter system. PTFE (purity greater than 99%, commercially available from Ultimate Materials Technology Company, Ltd.) with a diameter of 3 inches serving as an organic polymer target was put into the chamber. The PEN film with an area of 8 cm×8 cm serving as a substrate was put into the chamber. A gas mixture of an inert gas (argon with a purity of 4N, 20 sccm) and a reaction gas (oxygen with a purity of 4N, 10 sccm) was introduced into the chamber, and the chamber pressure was controlled to 5×10⁻³ Torr. Sputtering power of 350 W was applied to the TiO₂ inorganic target, and sputtering power of 40 W was simultaneously applied to the PTFE organic polymer target for 3 hours by a radio-frequency (RF) power supply, thereby forming an organic-inorganic composite film with a thickness of 540 nm on the substrate. The organic-inorganic composite film had a radius of curvature of 2.0 mm. The organic-inorganic composite film was put at a temperature of 40° C. under a relative humidity of 60% for 70 hours, and then analyzed for its water vapor transmission rate (about 14 mg/m²·day). FIG. 1 shows the XRD spectrum of the organic-inorganic composite film. As shown in FIG. 1, the organic-inorganic composite film is amorphous.

It will be apparent to those skilled in the art that various modifications and variations can be made to the disclosed methods and materials. It is intended that the specification and examples be considered as exemplary only, with a true scope of the disclosure being indicated by the following claims and their equivalents.

What is claimed is:

1. An organic-inorganic composite film, comprising:
homogeneous, amorphous, and nonporous material composed of carbon, fluorine and/or chlorine, oxygen and/or nitrogen, and inorganic element M, wherein the inorganic element M forms chemical bondings with carbon, fluorine and/or chlorine, oxygen and/or nitrogen, and wherein the chemical bondings have a bond length of less than 2.78 Å.

2. The organic-inorganic composite film as claimed in claim 1, wherein the inorganic element M forms at least three the chemical bondings, including aluminum(3), gallium(3), cobalt(3), iron(3), and silicon(4), titanium(4), germanium(4), palladium(4), vanadium(4), and chromium(5), selenium(6), or combinations thereof.

3. The organic-inorganic composite film as claimed in claim 1, comprising 1 atomic % to 25 atomic % of carbon, 5 atomic % to 30 atomic % of fluorine, 30 atomic % to 65 atomic % of oxygen and/or nitrogen, and 10 atomic % to 50 atomic % of M.

4. The organic-inorganic composite film as claimed in claim 1, having a water vapor transmission rate of less than 15 mg/m²·day.

5. A method of manufacturing an organic-inorganic composite film, comprising:
co-sputtering an inorganic target and a fluorine-containing organic polymer target, thereby simultaneously depositing atoms from the inorganic target and atoms from the fluorine-containing organic polymer target on a substrate to form an organic-inorganic composite film.

6. The method as claimed in claim 5, wherein the inorganic target comprises silicon, silicon oxide, silicon nitride, silicon oxynitride, silicon carbide, titanium, titanium oxide, titanium fluoride, titanium nitride, titanium carbide, vanadium, vanadium oxide, vanadium nitride, vanadium carbide, aluminum, aluminum oxide, aluminum fluoride, aluminum nitride, chromium, chromium oxide, chromium nitride, chromium carbide, selenium, selenium oxide, selenium carbide, gallium, gallium oxide, gallium nitride, germanium, germanium oxide, germanium carbide, cobalt, cobalt oxide, iron, iron oxide, iron fluoride, iron carbide, palladium, palladium oxide, or combinations thereof.

7. The method as claimed in claim 5, wherein the fluorine-containing organic polymer target comprises polyvinylidene difluoride, polytetrafluoroethylene, or combinations thereof.

8. The method as claimed in claim 5, wherein the substrate has a temperature of 25° C. to 150° C. during the step of co-sputtering an inorganic target and a fluorine-containing organic polymer target.

9. A method of manufacturing an organic-inorganic composite film, comprising:
co-sputtering a titanium oxide (TiO2) target and a polytetrafluoroethylene (PTFE) target, thereby simultaneously depositing atoms from the titanium oxide target and atoms from the polytetrafluoroethylene target on a substrate to form an organic-inorganic composite film.
